(19) United States
(12) Patent Application Publication
(10) Pub. No.: US 2014/0365196 A1
(43) Pub. Date: Dec. 11, 2014

(54) Infrastructure Model Generation System And Method

(71) Applicants: Bob Melander, Sigtuna (SE); Jan-Erik Mangs, Solna (SE)

(72) Inventors: Bob Melander, Sigtuna (SE); Jan-Erik Mangs, Solna (SE)

(73) Assignee: Telefonaktiebolaget L M Ericsson (publ), Stockholm (SE)

(21) Appl. No.: 13/818,938

(22) PCT Filed: Aug. 25, 2010
(86) PCT No.: PCT/IB10/02086

§ 371 Date: May 13, 2013

(51) Int. Cl. G06F 17/50; H04L 12/24; G06F 9/455

(52) U.S. Cl. CPC G06F 17/5009; G06F 9/455; H04L 41/12
USPC 703/13

(57) ABSTRACT

A computing system, interface and method for generating a model of a physical system. The method includes automatically collecting information about the physical system to generate an extended topology map of the physical system; automatically storing the extended topology map in a database; automatically processing the extended topology map to generate a model topology; and automatically generating, based on the model topology of the physical system, a simulation model or a virtualized model of the physical system.

### TECHNICAL FIELD

The present invention generally relates to systems, software and methods and, more particularly, to mechanisms and techniques for generating a model of an infrastructure.

### BACKGROUND

During the past years, the evolution of Internet and electronic devices using the Internet has increased dramatically. A multitude of content sources have entered the market for providing desired content, e.g., music, video, photos, etc. In order to satisfy the needs of their customers, who are located at various geographical positions, the infrastructure of these content sources has become more diversified and distributed. Cluster servers are provided in different geographical locations for providing faster access to the desired content. Thus, sophisticated networks are employed to link these cluster servers.

However, these networks and other distributed (IT) systems are complex infrastructures including a plethora of hardware and software units. When such systems are being installed, upgraded or modified, they need to be carefully tested before being placed into operation. This is especially important for business critical systems as a failure of one component may trigger the failure of a large part of the network or the cluster servers, thus resulting in unreliable service and unhappy customers.

There are numerous ways to test a new functionality, e.g., by simulation in simulators like OPNET Modeler or SimuLink (which are commercial tools for modeling, simulating and analyzing multidomain dynamic systems), or by running the new or modified functionality in a test environment (like a scaled down version of the final operational environment).

The advances in system virtualization during the last decade have opened convenient and cost effective ways to create powerful test environments. Entire systems (like an operator network) including a large numbers of nodes (e.g., routers, etc.) can be recreated as interconnected virtual instances of the actual equipment executing their software in a virtualization layer (e.g., hypervisors) on a cluster of servers. This virtualized environment then constitutes the test environment.

The advances in system virtualization have also opened other possibilities. Complete computer and network systems can now be moved or consolidated from existing legacy hardware installation to centralized data centers in the cloud and implemented in virtual environments. The advantages with these advances are numerous, e.g., computing and power resources can better be utilized; the system can be scaled up/down according to requirements; leverage economies of scale; etc. This trend in the industry partly drives the cloud and virtualization business.

For the evaluation and or tests of the new or modified functionalities to be valid and trustworthy, the simulation model or the virtualized test environment need to form a relevant abstraction of the real operational environment. In other words, if the model used for testing the functionality is a poor representation of the physical system, the results of the testing may be unreliable or irrelevant for the physical system. Thus, for networks or other distributed systems, it is desirable to be able to generate a suitable infrastructure model. The generation of the model refers to the proper configuration, organization and orchestration of simulation objects or virtual machines, e.g., interconnecting them analogously to the network topology of the operational network and configuring the virtual machines (VMs) with the correct operation system (OS) type and version as well as the installation of the required software on the VMs, e.g., routing daemons, etc. The same problem also exists when an existing computer and/or network system is to be consolidated into a centralized cloud computing center.

For large systems, the task of generating a model is time consuming and difficult to perform as a large amount of information related to the operational system has to be collected, analyzed and adapted to create the simulation model or (virtual) test environment. Many steps of this task still involve manual processes that are supported by limited tool availability.

Further, the existing virtualization management tools are focused on installing and managing virtual machines and not so much on configuring and interconnecting networks and running software inside the operating systems of the virtual machines.

Accordingly, it would be desirable to provide devices, systems and methods that avoid the afore-described problems and drawbacks.

### SUMMARY

Complex systems have to be modified or upgraded from time to time. Prior to implementing such processes, the operator of the system needs to know whether the intended modification or upgrade will work. For this reason, simulations of the physical systems may be used to provide these answers. Thus, an automatic tool that generates a model of a complex system is desirable.

According to an exemplary embodiment, there is a method for generating a model of a physical system. The method includes automatically collecting information about the physical system to generate an extended topology map of the physical system; automatically storing the extended topology map in a database; automatically processing the extended topology map to generate a model topology; and automatically generating, based on the model topology of the physical system, a simulation model or a virtualized model of the physical system.

According to another exemplary embodiment, there is a computing device for generating a model of a physical system. The computing device includes an interface configured to receive information about the physical system; a processor connected to the interface and configured to generate, based on the information, an extended topology map of the physical system; and a storage unit connected to the processor and configured to store the extended topology map. The processor is configured to process the extended topology map to generate a model topology, and to generate, based on the model topology of the physical system, a simulation model or a virtualized model of the physical system.

According to still another exemplary embodiment, there is an interface connected to a physical system for generating a model of the physical system. The interface includes a processor that runs computer instructions for automatically, collecting information about the physical system to generate an extended topology map of the physical system; storing the extended topology map in a database; processing the extended topology map to generate a model topology; and generating, based on the model topology of the physical system, a simulation model or a virtualized model of the physical system.

It is an object to overcome some of the deficiencies discussed in the previous section and to provide a functionality that generates an accurate model of a complex system. One or more of the independent claims advantageously provides such functionality.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a system having an infrastructure information collector function according to an exemplary embodiment;

FIG. 2 is a schematic diagram of a system having an infrastructure information adaptation function according to an exemplary embodiment;

FIG. 3 is a schematic diagram of a system having a simulation model/virtual world generation function according to an exemplary embodiment;

FIG. 4 is a flow chart illustrating a method for determining a topology of a physical system according to an exemplary embodiment; and

FIG. 5 is a schematic diagram of a computer system according to an exemplary embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of a physical system including various nodes or computing devices. However, the embodiments to be discussed next are not limited to these systems but may be applied to other existing systems.

Reference throughout the specification to “one embodiment” or “an embodiment” means that a particular feature, structure, or characteristic described in connection with an embodiment is included in at least one embodiment of the present invention. Thus, the appearance of the phrases “in one embodiment” or “in an embodiment” in various places throughout the specification is not necessarily all referring to the same embodiment. Further, the particular features, structures or characteristics may be combined in any suitable manner in one or more embodiments.

According to an exemplary embodiment, there is a capability or functionality that can be implemented in a system to generate or create a “snapshot image” of an operational distributed system (e.g., an operator network), and to generate a model of that system in a simulator or a virtualization environment. This functionality may be implemented in software, hardware or a combination thereof. The functionality may be retrofitted to existing systems, networks, etc.

According to an exemplary embodiment, a method for determining a topology of a physical system and for generating a model of the physical system includes a step of automatically collecting information about the physical system to generate an extended topology map of the physical system; a step of automatically storing the extended topology map in a database; a step of automatically processing the extended topology map to generate a model topology; and a step of automatically generating, based on the model topology of the physical system, a simulation model or a virtualized model of the physical system.

These steps are discussed next in more details. A brief discussion of the simulation model and the virtualized model of the physical system is provided now. It is noted that this discussion about the simulation model and the virtualized model is not limiting a definition of these concepts but rather an exemplification of possible meanings for these concepts. A virtualized model may be viewed as a simulation model with one or several hypervisors being the simulation engine. However, as most established network simulation tools are event-based simulators and do not rely on usage of virtualization hypervisors, a distinction is made between the simulation model and the virtualized model. With this possible distinction, a simulation model may be considered to include a topology of interconnected simulation objects (where an object is itself a simulation model of some real-world entity) and their configurations/settings (e.g., bandwidth of a link simulation object). A virtualized model may include a topology of interconnected virtual machines (with OS and software) and their configurations.

As noted, the above discussion is not exhaustive or complete and those skilled in the art may have different definitions for these two concepts. Some of them may view these concepts as essentially being the same. However, the above paragraph tries to provide possible differences between the two concepts.

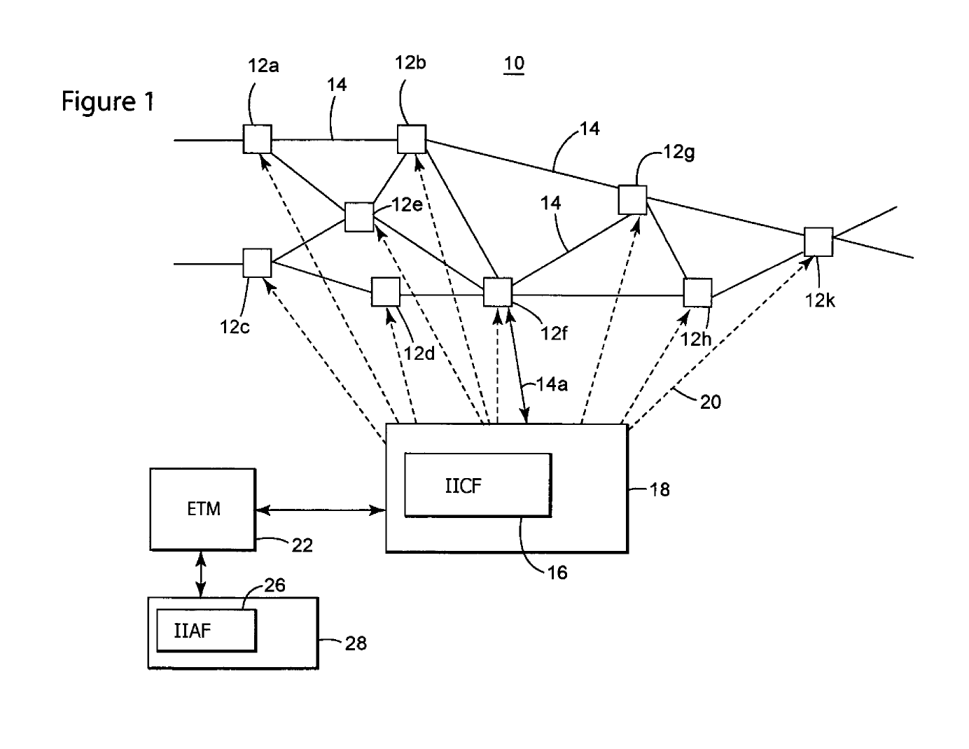

The steps of the method discussed above are now discussed in more details with regard to FIGS. 1-3. According to an exemplary embodiment illustrated in FIG. 1, there is a physical infrastructure or system 10 including plural nodes 12a to 12k and plural connections 14 between these nodes. The nodes 12a to 12k may be routers, switches, servers, computing devices, mobile phones, or any combination of these devices or other electronic devices. An Infrastructure Information Collector Function (IICF) 16 is provided for automatically collecting information about the nodes in the physical infrastructure (e.g., hardware configuration, operating system, software versions and configuration, etc.) and their relation (the network topology). The IICF function 16 may be implemented in a standalone node 18 or in an existing node 12a to 12k. The IICF function is configured to collect the above noted information by using connections 20, which are either physical connections between node 18 and the other nodes or logical connections implemented based on the physical connections 14. Such a physical connection 14 may exist between the node 18 and one or more of the nodes 12a to 12k. FIG. 1 shows for simplicity only one such connection 14a between node 18 and 12f.

In an exemplary embodiment, the IICF function 16 may be implemented by using an extended version of Open Shortest Path First (OSPF) and/or OSPF-Traffic Engineering (OSPF-TE) protocols as described, for example, in International Patent Application no. PCT/IB2010/001258, filed on Mar. 5, 2010 and assigned to the same assignee as the present application, the entire content of which is incorporated here by reference.

The OPSF protocol is now discussed briefly for a better understanding of the messaging that takes place among the various nodes in a network or cluster. A feature of the OPSF protocol and other protocols (Intermediate System to Intermediate System (IS-IS) protocol) is the link-state routing protocol. The link-state routing protocol is one of the two classes of routing protocols used in packet switching networks for computer communications, the other class being the distance-vector routing protocol.

The link-state protocol is performed by every switching node in the network (i.e., nodes that are prepared to forward packets; in the Internet, these are called routers). A basic concept of link-state routing is that every node constructs a map of the connectivity to the network, in the form of a graph, showing which nodes are connected to which other nodes. Each node then independently calculates the next best logical hop from it to every possible destination in the network. The collection of the best next hops will then form the node's routing table.

The link-state protocol contrasts with distance-vector routing protocols, which work by having each node share its routing table with its neighbors. In a link-state protocol the only information passed between nodes is connectivity related. In other words, each router “tells the world” about its neighbors.

The link-state protocol instructs each node to periodically, or in case of connectivity changes, to make up a short message, the link-state advertisement (LSA), which identifies the node which is producing it, identifies all the other nodes to which it is directly connected, and includes a sequence number, which increases every time the source node makes up a new version of the message. This message is then flooded throughout the network to the other nodes.

Another protocol to which the exemplary embodiments may be applied is the IS-IS. The IS-IS is a protocol used by network devices (e.g., routers) to determine the best way to forward datagrams through a packet-switched network, a process called routing. IS-IS is not an Internet standard.

Thus, the novel IICF function 16 may be implemented in these or other signaling protocols for collecting the necessary information about the system 10.

In another exemplary embodiment, the IICF function may be implemented using a protocol that extends Link Layer Discovery Protocol (LLDP). Such a protocol is used by network devices for advertising their identity, capabilities, and neighbors.

The IICF function 16 may be configured to use one or more of the LLDP, OSPF-TE or other tools as traceroute, port scanning, Simple Network Management Protocol (SNMP), Remote Network Monitoring (RMON), etc. The IICF function 16 may be configured to use one of the protocols first, then a second of the protocols and so on. Also, the IICF function 16 may be configured to simultaneously run one or more of these protocols. In another application, the user may configure the IICF function 16 to run one protocol for a part of the network and another protocol for another part of the network, simultaneously or sequentially. The IICF function 16 may be configured to be triggered by the operator of the network, at specific times, or by one or more events (e.g., network change).

The information collected by the IICF function 16 (by either protocol) may be stored in an extended topology map (ETM), which may be stored in a storage device or database 22. A new functionality, the Infrastructure Information Adaptation Function (IIAF) 26 is configured to have access to the extended topology map 22 and retrieve any desired information stored in the map 22. It is noted that the extended topology map 22 includes all the information retrieved by the IICF function 16. In one application, it is possible that a user augments that information by manually adding more information about the physical network 10.

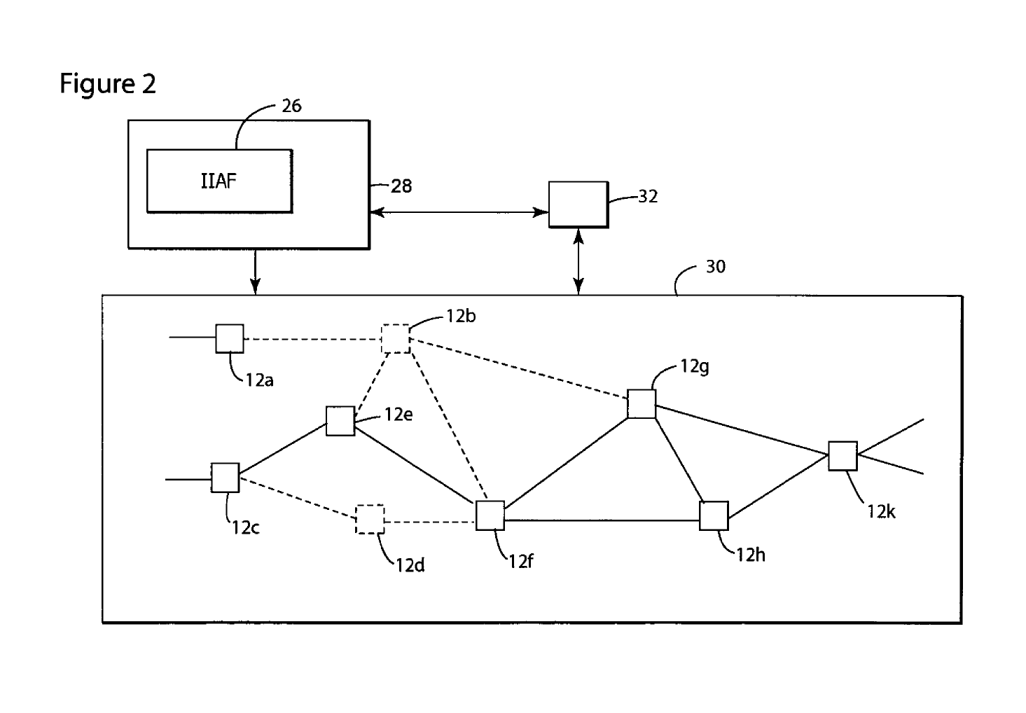

The IIAF function 26 may be implemented in a standalone device 28, in the node 18, in one of the nodes 12a to 12k, or a combination of these devices. For simplicity, the figures show the IIAF function 26 implemented in the standalone device 28. The IIAF function 26 is configured to automatically process the extended topology map to produce a model topology 30 with a suitable abstraction level as illustrated in FIG. 2. FIG. 2 shows that part of nodes (e.g., 12b and 12d) are not present in the model topology 30 and also their connections to the nodes that are present. For example, non-relevant nodes 12b and 12d may be filtered out. However, the model topology 30 may be identical to the extended topology map 22. The processing performed by the IIAF function 26 may include removing nodes, removing connections, substituting a node or connection with another one, changing properties of the nodes or connections, etc.

In addition, the IIAF function 26 may determine and display one or more of the characteristics of the determined nodes 12a to 12k, for example, node 12a is a HP ProLiant device, node 12e is a Redback SE 1200 device, etc. The IIAF function 26 may be configured to automatically exclude some nodes, components, etc, for example, based on a predetermined list, or by calculating certain conditions, e.g., if the bandwidth of a specific connection is less than 10 kb, remove that link. The model topology 30 generated by the IIAF function 26 may be stored, for example, in storage device 32.

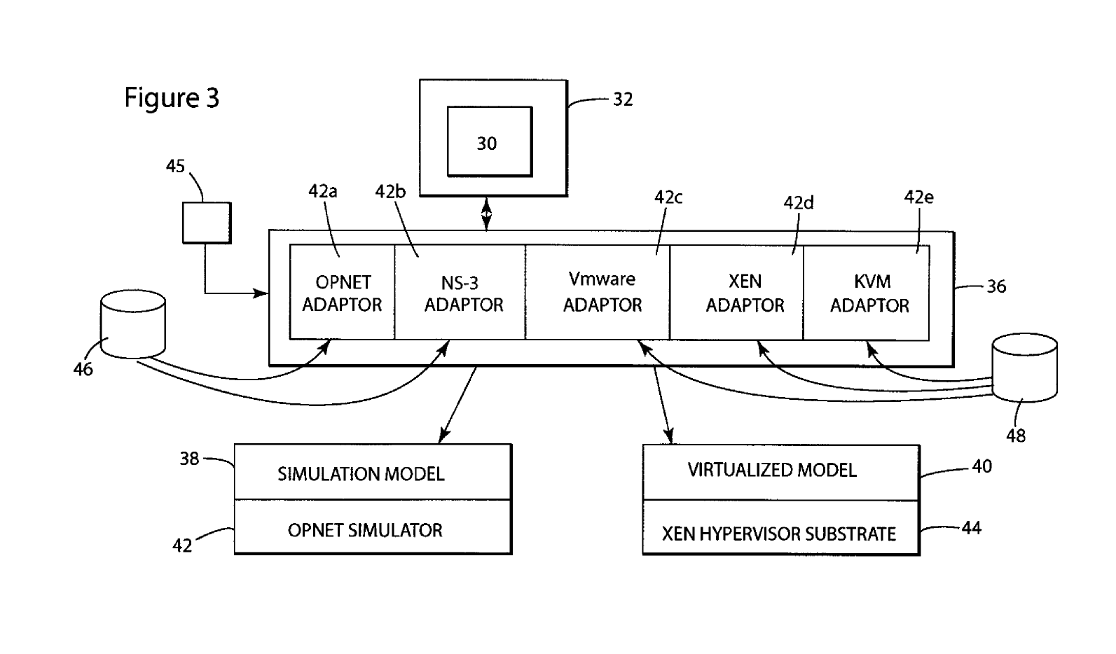

According to an exemplary embodiment shown in FIG. 3, a Simulation Model/Virtual World Instantiator Function (IF) 36, which may be implemented in any of the nodes discussed above, is configured to read the information from the model topology 30 and to process it in order to generate an appropriate simulation model 38 or a virtualized model 40 depending of an output selector 42a to 42e. More specifically, the IF function 36 applies to the information from the model topology 30 a dedicated adaptor 42a to 42e for generating the simulation model 38 or the virtualized model 40 as shown in FIG. 3. The dedicated adaptor 42a to 42e may be one of an OPNET adaptor 42a, Ns-3 adaptor 42b, Vmware adaptor 42c, XEN adaptor 42d or KVM adaptor 42e. A dedicated adaptor is selected, e.g., manually, based on the platform that is capable to display the models 38 and 40, for example, an OPNET adaptor 42a for an OPNET simulator. The exemplified adaptors are just a few of the well known simulators. More or less adaptors may be used with the IF function 36. These adapters are configured to “translate” the information from the model topology 30 into language specific instructions, commands, etc. of the specific language or platform OPTNET, Ns-3, etc. that will display the final model. The user of the IF function 36 may input data via a user interface 45 to control which adaptor 42a to 42e to be selected.

The simulation model 38 or the virtualized model 40 may be displayed in an appropriate environment, as for example, the OPNET simulator 42 and the XEN hypervisor substrate 44, respectively. An appropriate adaptor is automatically applied by the IF function 36 for achieving this task. In creating the simulation model 38 or the virtualized model 40, the IF function 36 may collect simulation objects from a simulation object repository 46 or VM images from a VM image repository 48. However, this is only one example and those skilled in the art would appreciate that there may be a library of predetermined images for any node and for any simulation or substrate medium not only for simulator 42 and the substrate 44 shown in FIG. 3. In other words, the novel IF function 36 may be configured to have an appropriate adaptor for any desired platform or substrate.

As an example, there could be preconfigured VM images for Redback SE1200 router and these preconfigured images may be stored in the VM image repository 48. Thus, the IF function 36 may use this predetermined image to represent node 12e in the virtualized model.

According to an exemplary embodiment, some of the nodes 12a to 12k may be mapped to real machines instead of simulation models or virtual machines, thereby allowing the test environment to interwork with real machines.

A management tool may be configured to include one or more of the IICF, IIAF, and IF functions discussed above. Such a management tool provides an automated way for a cloud computing provider to transfer an existing legacy computer and network installations into the cloud. This would reduce the time and effort to perform this operation compared to current tools.

One or more of the embodiments discussed above provides an automated way to set up, test, and evaluate environments for distributed systems. The model generated by such a novel tool may be a snapshot of the real operational system. As was discussed above, the novel functions may be implemented for both simulators and hypervisors to generate either simulation models or virtualized models.

As also discussed above, one exemplary embodiment allows real machines to interwork with the generated test environment (i.e., the simulation model or the virtualized model).

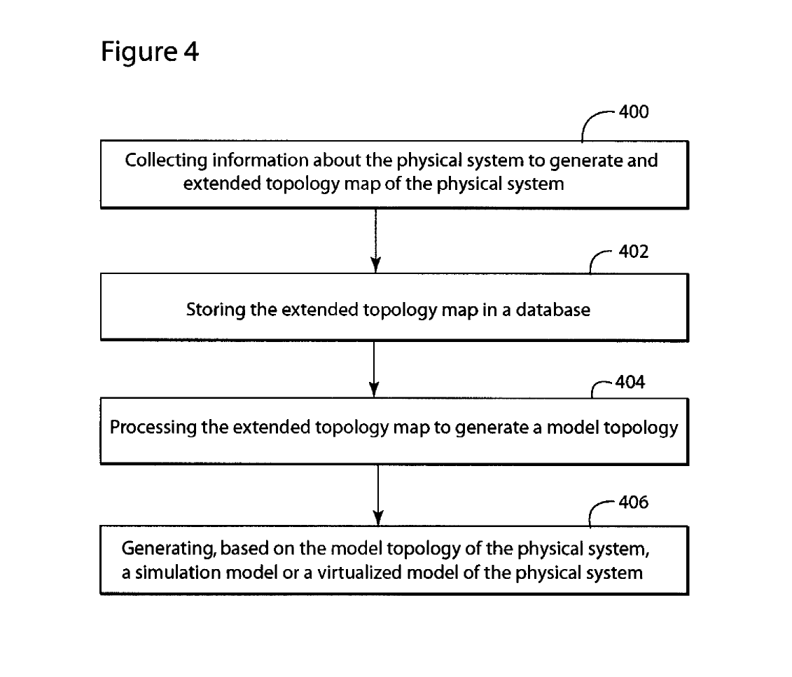

According to an exemplary embodiment illustrated in FIG. 4, there is a method for generating a model of the physical system. The method includes a step 400 of automatically collecting information about the physical system to generate an extended topology map of the physical system; a step 402 of automatically storing the extended topology map in a database; a step 404 of automatically processing the extended topology map to generate a model topology; and a step 406 of automatically generating, based on the model topology of the physical system, a simulation model or a virtualized model of the physical system.

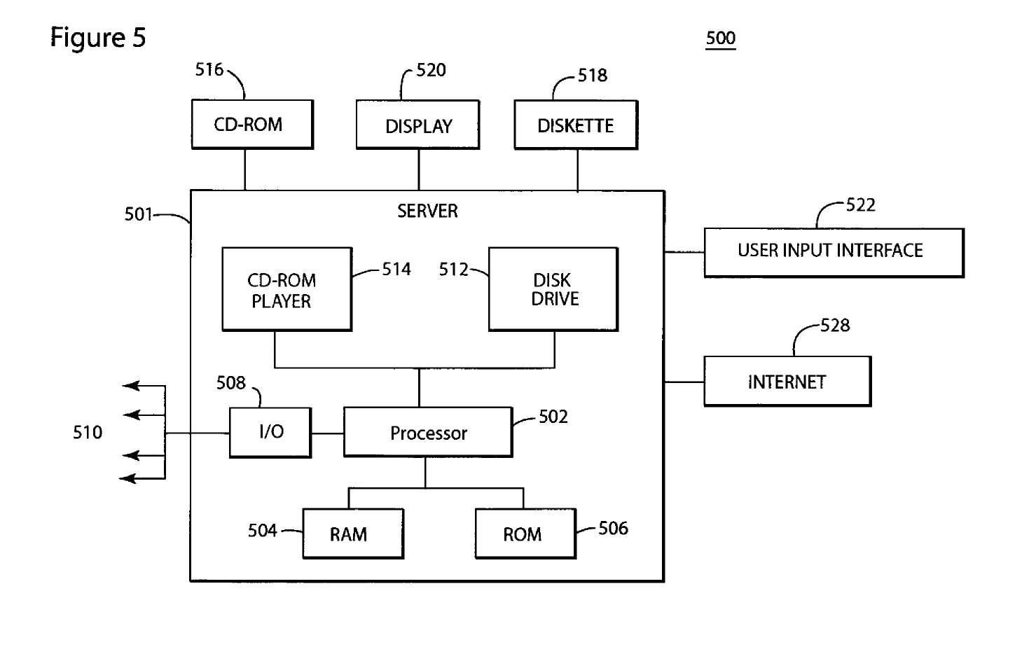

For purposes of illustration and not of limitation, an example of a computing system and/or interface capable of carrying out operations in accordance with the exemplary embodiments is illustrated in FIG. 5. It should be recognized, however, that the principles of the present exemplary embodiments are equally applicable to other standard computing systems.

Hardware, firmware, software or a combination thereof may be used to perform the various steps and operations described herein. The computing structure 500 of FIG. 5 is an exemplary computing structure that may be used in connection with such a system.

The exemplary computing arrangement 500 suitable for performing the activities described in the exemplary embodiments may include server 501, which may correspond to any of nodes 12a to 12k shown in FIGS. 1 and 2. Such a server 501 may include a central processor (CPU) 502 coupled to a random access memory (RAM) 504 and to a read-only memory (ROM) 506. The ROM 506 may also be other types of storage media to store programs, such as programmable ROM (PROM), erasable PROM (EPROM), etc. Computer instructions related to the functionalities 16, 26, and 36 may be stored in these memories and the processor 502 may activate these functions when necessary. The processor 502 may communicate with other internal and external components through input/output (I/O) circuitry 508 and bussing 510, to provide control signals and the like. The processor 502 carries out a variety of functions as is known in the art, as dictated by software and/or firmware instructions.

The server 501 may also include one or more data storage devices, including hard and floppy disk drives 512, CD-ROM drives 514, and other hardware capable of reading and/or storing information such as DVD, etc. In one embodiment, software for carrying out the above discussed steps may be stored and distributed on a CD-ROM 516, diskette 518 or other form of media capable of portably storing information. These storage media may be inserted into, and read by, devices such as the CD-ROM drive 514, the disk drive 512, etc. The server 501 may be coupled to a display 520, which may be any type of known display or presentation screen, such as LCD displays, plasma display, cathode ray tubes (CRT), etc. A user input interface 522 is provided, including one or more user interface mechanisms such as a mouse, keyboard, microphone, touch pad, touch screen, voice-recognition system, etc.

The server 501 may be coupled to other computing devices, such as the landline and/or wireless terminals and associated watcher applications, via a network. The server may be part of a larger network configuration as in a global area network (GAN) such as the Internet 528, which allows ultimate connection to the various landline and/or mobile client/watcher devices.

The disclosed exemplary embodiments provide a computing system, a method, an interface and a computer program product for determining a simulation model or a virtualized model of a physical system. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

As also will be appreciated by one skilled in the art, the exemplary embodiments may be embodied in a wireless communication device, a telecommunication network, as a method or in a computer program product. Accordingly, the exemplary embodiments may take the form of an entirely hardware embodiment or an embodiment combining hardware and software aspects. Further, the exemplary embodiments may take the form of a computer program product stored on a computer-readable storage medium having computer-readable instructions embodied in the medium. Any suitable computer readable medium may be utilized including hard disks, CD-ROMs, digital versatile disc (DVD), optical storage devices, or magnetic storage devices such a floppy disk or magnetic tape. Other non-limiting examples of computer readable media include flash-type memories or other known memories.

Although the features and elements of the present exemplary embodiments are described in the embodiments in particular combinations, each feature or element can be used alone without the other features and elements of the embodiments or in various combinations with or without other features and elements disclosed herein. The methods or flow charts provided in the present application may be implemented in a computer program, software, or firmware tangibly embodied in a computer-readable storage medium for execution by a specifically programmed computer or processor.

1. A method for generating a model of a physical system including a plurality of interconnected nodes, the method comprising:
automatically collecting information about the physical system to generate an extended topology map of the physical system wherein the extended topology map includes all the collected information about the physical system;
automatically storing the extended topology map in a database;
automatically processing the extended topology map to generate a model topology wherein the model topology map excludes non-relevant portions of the physical system;
automatically generating, based on the model topology of the physical system, a simulation model or a virtualized model of the physical system wherein the virtualized model includes a topology of the interconnected nodes of the physical system with operating systems and software; and
automatically transferring the model of the physical system to a cloud computing center.

2. The method of claim 1, further comprising:
activating an infrastructure information collector function for collecting the information;
activating an infrastructure information adaptation function for processing the extended topology map; and
activating a simulation model/virtual world generation function for generating the simulation model or the virtualized model.

3. The method of claim 1, further comprising:
using, for collecting the information, a combination of at least two protocols from a group of protocols, wherein the group includes at least a link layer discovery protocol (LLDP) and open shortest path first (OSPF) protocol.

4. The method of claim 1, wherein the system includes plural nodes, a node being one or more of routers, switches, servers and computing elements.

5. The method of claim 1, wherein the information is indicative of hardware configuration of the nodes, operating systems of the nodes, software versions of software running on the nodes, and relations between the nodes.

6. The method of claim 1, wherein the model topology describes a subset of nodes of all the nodes of the extended topology map and their relations.

7. The method of claim 1, wherein the step of processing the extended topology map to generate a model topology comprises:
excluding nodes or modifying properties of the nodes that make up the extended topology map of the physical system via a computer interface to generate the model topology.

8. The method of claim 1, further comprising:
manually selecting whether the simulation model or the virtualized model is generated.

9. The method of claim 8, further comprising:
when the simulation model is generated, collecting simulation objects from a simulation objects repository for modeling various nodes of the physical system.

10. The method of claim 9, wherein the step of generating further comprises:
applying an adaptor to output the simulation model of the physical system in a format that is readable by a commercially available simulator.

11. The method of claim 8, further comprising:
when the virtualized model is generated, collecting virtual machine objects from a virtual machine image repository for modeling various nodes of the physical system.

12. The method of claim 11, wherein the step of generating further comprises:
applying an adaptor to output the virtualized model of the physical system in a format that is readable by a commercially available hypervisor substrate.

13. The method of claim 1, further comprising:
generating the simulation model or the virtualized model to have at least one node of the physical system implemented into one or more physical machines.

14. A computing device for generating a model of a physical system, the computing device comprising:
an interface configured to receive information about the physical system;
a processor connected to the interface and configured to generate, based on the information, an extended topology map of the physical system wherein the extended topology map includes all the information received about the physical system; and
a storage unit connected to the processor and configured to store the extended topology map, wherein
the processor is configured to process the extended topology map to generate a model topology wherein the model topology map excludes not-relevant portions of the physical system,
to generate, based on the model topology of the physical system, a simulation model or a virtualized model of the physical system wherein the virtualized model includes a topology of the interconnected nodes of the physical system with operating systems and software, and
to transfer the model of the physical system to a cloud computing center.

15. The computing device of claim 14, wherein the processor is configured to run computer instructions that,
activate an infrastructure information collector function for collecting the information;
activate an infrastructure information adaptation function for processing the extended topology map; and
activate a simulation model/virtual world generation function for generating the simulation model of virtualized model.

16. The computing device of claim 14, wherein the processor is configured to:
exclude nodes or modify properties of nodes that make up the extended topology map of the physical system via a computer interface to generate the model topology.

17. The computing device of claim 14, wherein the processor is configured to:
select, based on an input from a user, whether the simulation model or the virtualized model is generated;
when the simulation model is generated, to collect simulation objects from a simulation objects repository for modeling various nodes of the physical system and to apply an adapter for outputting the simulation model of the physical system in a format that is readable by a commercially available simulator; and
when the virtualized model is generated, to collect virtual machine objects from a virtual machine image repository for modeling various nodes of the physical system, and to apply an adapter for outputting the virtualized model of the physical system in a format that is readable by a commercially available hypervisor substrate.

18-19. (canceled)

20. The computer device of claim 14, wherein the processor is configured to use, for collecting the information, a combination of at least two protocols from a group of protocols, wherein the group includes at least a link layer discovery protocol (LLDP) and open shortest path first (OSPF) protocol.
